(19) United States
(12) Patent Application Publication
(10) Pub. No.: US 2009/0315708 A1
(43) Pub. Date: Dec. 24, 2009

(54) METHOD AND SYSTEM FOR LIMITING AUDIO OUTPUT IN AUDIO HEADSETS

(76) Inventors: John Walley, Ladera Ranch, CA (US); Louis Pandula, Sunnyvale, CA (US)

Correspondence Address: MCANDREWS HELD & MALLOY, LTD, 500 WEST MADISON STREET, SUITE 3400, CHICAGO, IL, 60661, US

(21) Appl. No.: 12/192,965

(22) Filed: Aug. 15, 2008

Related U.S. Application Data
(60) Provisional application No. 61/074,044, filed on Jun. 19, 2008.

(51) Int. Cl. G08B 21/00; H03G 3/00

(52) U.S. Cl. 340/540; 381/107

(57) ABSTRACT

Aspects of a method and system for limiting an audio signal output in an audio device are provided. An exposure meter may provide measurements of SPL values of the audio signal. When a volume or exposure level of the audio signal may approach or exceed a specified limit, the audio signal may be enforced to a predetermined limit. The audio signal may be an input or an output signal of a speaker of an audio device such as a stereo headset. A trend of the measured SPL values may be predicted based on the measured SPL values and device specific reference SPL values. When the volume or exposure level of the audio signal may not be within the specified limit, the audio signal may be limited and an alarm may be sent out to listener. A set of audio volume level parameters may be determined and applied, accordingly.

### CROSS-REFERENCE TO RELATED APPLICATIONS/INCORPORATION BY REFERENCE

This patent application makes reference to, claims priority to and claims benefit from U.S. Provisional Patent Application Ser. No. 61/074,044 filed on Jun. 19, 2008.

The above stated patent application is hereby incorporated herein by reference in its entirety.

### FIELD OF THE INVENTION

Certain embodiments of the invention relate to audio processing. More specifically, certain embodiments of the invention relate to a method and system for limiting audio output in audio headsets.

### BACKGROUND OF THE INVENTION

Audio and/or video playback devices such as portable DVD and CDs players, hard disk players, Flash players, and other music player generally allow a user to set various volume levels so as to vary the intensity of the sound produced by one or more speakers connected thereto. However, in a noisy environment such as subway train, street, park, when a user listens to music through a headset, for example, an earphone or a headphone the user may experience great difficulty in listening to the sound due to the surrounding noise. As a result, the user may have to increase the volume so that the audio content may be heard above the background noise. The increased volume may cause short term or long term damage to the user's auditory organs. Furthermore, even though the volume has been increased, the background noise may still prevent the user from hearing certain portions of the audio content, especially those portions of the audio content having relatively small amplitude.

In some instances where an individual may listen music in a high background noise environment, the individual may also force a portion of an audio device housing a speaker against his/her ear with greater force in order to hear the sound clearly. However, the resulting acoustic characteristics of the speaker may change. For example, when a user of a device forces an ear piece on that audio device against their ear, this may cause low frequency portions of a frequency response for a speaker located in the ear piece to change. As a result, sound coming out of the speaker may take on undesirable characteristics. For example, a low frequency portion of the speaker output may have amplitude that may be higher than desired, thereby resulting in too much bass in the speaker output.

Further limitations and disadvantages of conventional and traditional approaches will become apparent to one of skill in the art, through comparison of such systems with the present invention as set forth in the remainder of the present application with reference to the drawings.

### BRIEF SUMMARY OF THE INVENTION

A system and/or method is provided for limiting audio output in audio headsets, substantially as shown in and/or described in connection with at least one of the figures, as set forth more completely in the claims.

These and other advantages, aspects and novel features of the present invention, as well as details of an illustrated embodiment thereof, will be more fully understood from the following description and drawings.

### BRIEF DESCRIPTION OF SEVERAL VIEWS OF THE DRAWINGS

FIG. 1 is a block diagram of an exemplary audio headset that enables limiting of audio output, in accordance with an embodiment of the invention.

FIG. 2 is a block diagram that illustrates an exemplary digital audio processor that enables limiting of audio output in audio headsets, in accordance with an embodiment of the invention.

FIG. 3 is a flow chart that illustrates exemplary steps for determining audio signal processing parameters, in accordance with an embodiment of the invention.

### DETAILED DESCRIPTION OF THE INVENTION

Certain embodiments of the invention may be found in a method and system for limiting audio output in audio headsets. Various aspects of the invention may utilize an exposure meter may used to provide measurements of speaker characteristics such as the sound pressure level (SPL) values of an audio signal. In instances when a volume or exposure level of the audio signal may approach or exceed a specified limit, the audio signal may be enforced to a predetermined limit. The audio signal may be an input or an output signal of a speaker of an audio device such as a stereo or monaural (mono) headset. The stereo headset may be enabled to predict a trend of the measured SPL values over a certain time period based on the SPL measurements and device specific reference SPL values. In instances when the volume or exposure level of the audio signal may be approaching the specified limit, the audio signal may be limited and/or an alarm or alert signal, which may be an audio and/or visual alert, may be communicated to a listener. Audio volume level parameters, such as, for example, the coefficients of a speaker equalizer, the loudness level of a loudness control, and/or the volume level settings of a volume control, may be determined and applied.

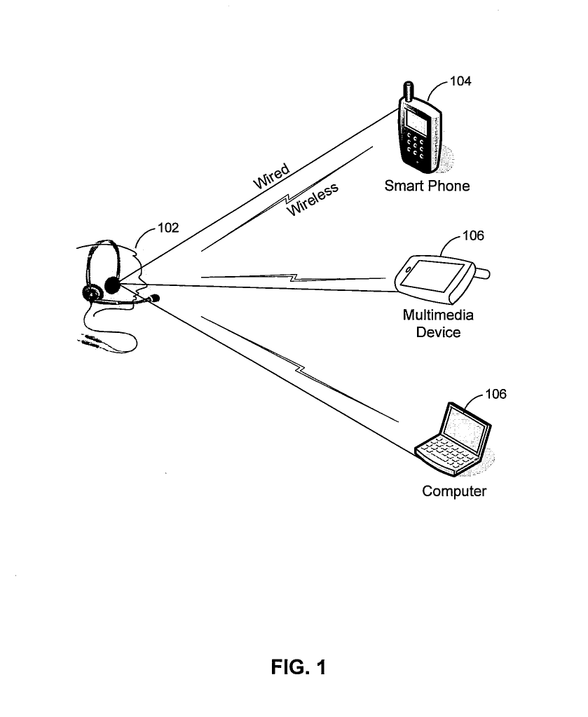

FIG. 1 is a block diagram of an exemplary audio headset that enables limiting of audio output, in accordance with an embodiment of the invention. Referring to FIG. 1, there is shown a headset 102, a smart phone 104, a multimedia device 106, and a computer 108.

The headset 102 may comprise suitable logic circuitry and/or code that may be enabled to receive electrical signals representative of audio signals and may convert these received electrical signals to audible signals. The headset 102 may be coupled to various devices such as the smart phone 104, the multimedia device 106, and/or the computer 108 to listen to some audio contents such as music and speech. The headset 102 may be a wired or wireless headset. In this regard, the headset 102 may be plugged into the multimedia device 106 or a peripheral device coupled to the multimedia device 106, or the headset 102 may be infrared, Bluetooth and/or ZigBee capable. Notwithstanding, the connection between the headset 102 and, for example, the multimedia device 106, may enable the headset 102 to access to the audio content stored in the multimedia device 106 and/or receive audio signals from the multimedia device 106. The headset 102 may allow a listener to play, pause, forward, reverse, and/or adjust volume, base, and treble of audio content such as voice or music. The headset 102 may be enabled to limit a long term exposure from high volume level to the listener by using a SPL meter and various control algorithms. Various techniques such as speaker equalization, volume control, and/or loudness control may be used to reduce potential for hearing damage.

The smart phone 104 may comprise suitable logic circuitry and/or code that may be enabled to generate electrical signals representative of audio signals and may communicate these generated electrical signals to the headset 102. The smart phone 104 may be enabled to communicate with the headset 102 via a wired and/or a wireless connection such as infrared, Bluetooth and/or ZigBee. The smart phone 104 may be enabled to retrieve media content comprising from a remote source such as a server, and/or store media content within internal memory or removable memory. The media content may comprise video, data, and/or audio signals such as voice and/or music. An audio portion of the media content consumed during playback on the smart phone 104 may be communicated to the headset 102, the latter of which may be enabled to utilize speaker equalization, volume control, and/or loudness control so as to mitigate potential hearing damage.

The multimedia device 106 may comprise suitable logic circuitry and/or code that may be enabled to generate electrical signals representative of audio signals and may communicate these generated electrical signals to the headset 102. The multimedia device 106 may be enabled to communicate with the headset 102 via a wired and/or a wireless connection such as infrared, Bluetooth and/or ZigBee. The multimedia device 104 may be enabled to retrieve media content from a remote source such as a server, and/or store media content within internal memory or removable memory. An audio portion of the media content consumed during playback on the multimedia device 104 may be communicated to the headset 102, the latter of which may be enabled to utilize speaker equalization, volume control, and/or loudness control so as to mitigate potential hearing damage.

The computer 108 may comprise suitable logic circuitry and/or code that may be enabled to generate electrical signals representative of audio signals and may communicate these generated electrical signals to the headset 102. The computer 108 may be enabled to communicate with the headset 102 via a wired and/or a wireless connection such as infrared, Bluetooth and/or ZigBee. The computer 108 may be enabled to retrieve media content from a remote source such as a server, and/or store media content within internal memory or removable memory. An audio portion of the media content consumed during playback on the computer 108 may be communicated to the headset 102, the latter of which may be enabled to utilize speaker equalization, volume control, and/or loudness control so as to mitigate potential hearing damage.

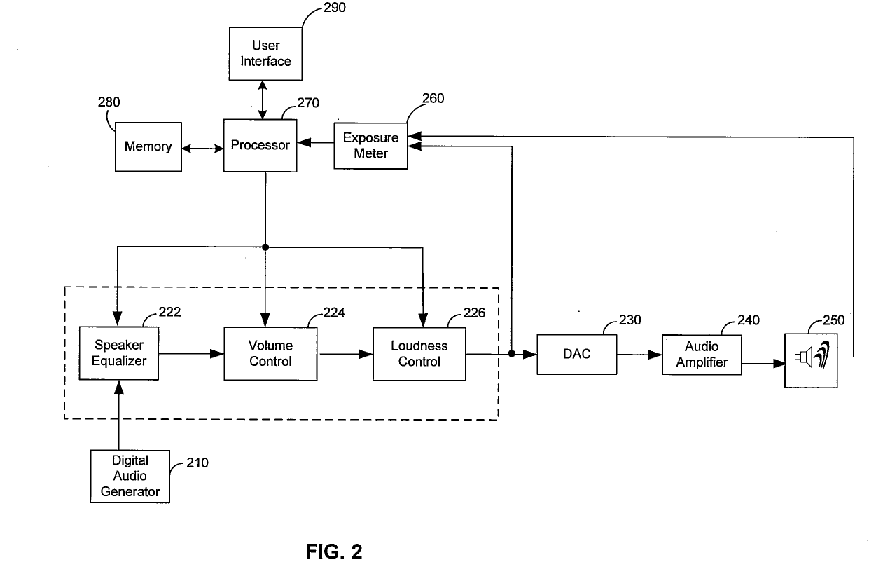

FIG. 2 is a block diagram that illustrates an exemplary digital audio processor that enables limiting of audio output in audio headsets, in accordance with an embodiment of the invention. Referring to FIG. 2, there is shown a digital audio generator 210, speaker equalizer 222, volume control 224, loudness control 226, DAC 230, audio amplifier 240, speaker 250, exposure meter 260, processor 270, memory 280, and user interface 290.

The digital audio generator 210 may comprise suitable logic, circuitry and/or code that may be integrated and/or communicatively coupled to a transmission module for transformation between the electromagnetic signals and the digital audio signals. The digital audio generator 210 may be a digital processor that may receive an audio signal from a variety of difference sources, such as, for example, a CD, and digitized radio or audio signal. Alternatively, the digital audio generator 210 may enable analog to digital conversion. In this regard, the digital audio generator 210 may receive an analog audio signal from an analog source and convert this received analog audio signal to a digital bitstream.

The speaker equalizer 222 may comprise suitable logic, circuitry and/or code that may enable compensating, on a frequency basis, for the effects of the signal path on the magnitude and the phase of an audio signal. The speaker equalizer 222 may also enable modifying the audio signal prior to playback by the speaker 250 in order to create some desired speaker response that may be the intrinsic speaker response. In other words, the speaker equalizer 222 may effectively shape the audio signal to the desired response of the speaker or headset. The speaker equalizer 222 may be implemented variety of different ways to provide an enhancement of the received audio signal and remove or mitigate the effects of environment noise outside a desired range. A flat audio response, which may refer to the resulting frequency versus amplitude gain, across the entire frequency spectrum, may result in the sound spectrum to pass through the speaker without audible degradation.

In general, when sound such as music may be reproduced by an audio system, the sound waves may undergo reflection and absorption during transmission over a signal path. The signal path may have unique transmission characteristics, which may alter the magnitude and/or phase of the sound waves differently for various frequency components, thereby producing degenerated sound. In this regard, the speaker equalizer 222 may be enabled to provide various other levels of equalization other than a flat spectrum. For example, in instances where there may be deficiencies in the speaker or headset, the sound spectrum might be shaped to create a particular sound effect, to enhance intelligibility of an audio signal, and/or to compensate for the listening environment, the listener's particular hearing characteristics and/or a listener's desired preference. The frequency shaping may effectively shift beyond a desired digital audio spectrum thus resulting in a substantially constant SNR over the desired digital audio spectrum.

The volume control 224 may comprise suitable logic, circuitry and/or code that may enable providing a volume level of audio signals to be amplified or attenuated for audible signals and controlling the volume of an audio signal reproduced at an audio device. The volume level may be derived based on the speaker characteristics through the output of the exposure meter 260.

The exposure meter 260 may comprise suitable logic, circuitry and/or code to enable, for example, monitoring audio volume values that a listener may be exposed to, and passing the measurements to the processor 270.

The loudness control 226 may comprise suitable logic, circuitry and/or code that may enable controlling enhancement of the low-frequency components of the audio signal so as to compensate for the lower response of the human ear to low-frequency sounds. The loudness control 226 may improve the physiological sensation produced by the sound.

The digital to analog converter (DAC) 230 may comprise suitable logic, circuitry and/or code that may enable conversion of an input digital signal to a resulting analog signal. The output of DAC 230 may be accessed directly for storage, or for further processing, such as, for example, in digital audio mixing applications.

The audio amplifier 240 may comprise suitable logic, circuitry and/or code that may enable amplification of audio signals and outputting the resulting amplified analog signal to speaker 250.

The speaker 250 may comprise suitable logic, and/or circuitry that may broadcast the audio signals. The amplitude of an audio signal may be referred to as sound pressure level (SPL), and the measurement unit may be the Decibel (DB or DBA).

The processor 270 may comprise suitable logic, circuitry and/or code that may be enabled to predict a tendency of speaker performance such as the measured SPL values based on the SPL measurements and respective device specific reference SPL values. The processor 270 may be enabled to compare measured SPL values to an exposure threshold to determine whether changes to the volume level settings may be required. In instances where the measured SPL may approach or exceed the exposure threshold shortly, the processor 270 may enforce the audio signal in a specified limit. Based on the specified limit, the processor 270 determine a set of audio signal processing parameters such as the coefficients of the speaker equalizer 222, the volume settings of the volume control 124, and/or loudness level for the loudness control 226. The processor 270 may generate an alert signal and send to the listener when the exposure level approaches and/or exceeds certain thresholds shortly.

The memory 280 coupled to the processor 270 may be FLASH memory, electronically erasable programmable memory (EEPROM), or DRAM. The memory 280 may comprise instructions executable by, for example, the processor 270 and/or the user interface 290. The instructions may comprise user configuration information such as maximum volume level and exposure threshold settings and reference SPL values. A SPL look-up table may be stored in the memory 280. The SPL look-up table may comprise mappings between device specific reference SPL values and respective volume levels. The SPL look-up table may provide a unique volume level for a given SPL value. The SPL look-up table may be used to evaluate dynamic performance of the speaker 250 by comparing the measured SPL values with respective reference SPL values in the SPL look-up table.

A user interface 290 may comprise suitable logic, circuitry and/or code that may be enabled to provide manual or programmable controllability to deliver a control signal to the processor 270 to indicate user preferences to adjust audio signal processing settings at the speaker equalizer 222, the volume control 224 and/or loudness control 226. The user interface 190 may be connected to the input of the processor 270 and may enable a user to input custom settings on gain control on speaker equalizer 222, volume control 224 and loudness control 226.

In operation, electric signals from an audio source such as voice or music may be transformed to audio signals via the audio generator 210. The digital audio generator 210 may provide a digital audio signal, such as, for example, a digital bitstream, to the speaker equalizer 222. The audio signal may be processed by the speaker equalizer 222 accordingly. The speaker equalizer 222 may provide compensation for any environmental degeneration in the audio signal, on a frequency basis, so as to enhance the received audio signal and/or remove or mitigate the environment noise outside a desired range. The output of the equalizer 222 may be supplied to the input of a volume control 224 for attenuating (or amplifying) the audio signal by a predetermined value.

The volume control 224 may output to the loudness control 226. The loudness control 126 may be carried out so as to strengthen the specific signal components in an inputted audio signal by raising an output level by a predetermined level substantially uniformly for the signal of the specific frequency spectrum. An output level for signals other than the signal of the specific frequency spectrum may not be changed. The loudness control 226 and volume control 224 may have a fairly high resolution on gain control, for example, of the order of 1 dB, whereas the speaker equalizer 222 generally may have a fairly low resolution on gain control, for example, of the order of a few dB. The gain attenuation or amplification levels on speaker equalizer 222, volume control 224 and loudness control 226 may be controlled and/or signaled by the processor 270. The processor 270 may be coupled to the memory 280, the user interface 290, and the exposure meter 260.

The exposure meter 260 may measure the speaker characteristics such as the sound pressure level across the entire audio spectrum. The sound pressure level measurements may be made in either closed loop (output of loudness control 226) or open loop (output of speaker 250). For closed loop acoustic response measurement, the output of loudness control 226 may be accessed directly for measuring the audio signal amplitude. The exposure meter 260 may be enabled to monitor digital samples inside the audio device which minimizes sound reflections, so the measurement may record only the speaker's performance without the influence of echoes and other environmental effects. An open loop measurement may be used for some circumstances where it may be desirable to measure the response of a listening environment. In this case, the measurements may be taken directly from the sound from the speaker which includes effects from the environment, such as, for example, the influence of echoes.

The exposure meter 260 may provide information about an acoustic condition of the speaker 250 in an audio device such as the headset 102, and the resulting measured SPL values may be delivered to the processor 270 for further processing. The processor 270 may evaluate performance of the speaker 250 by comparing the received SPL measurements with the respective reference SPLs and/or user preferred settings stored in the memory 180. The processor 270 may predict a tendency of the speaker performance based on the evaluation. In instances where a maximum volume level of the speaker 250 may be reached or exceeded shortly, the processor 270 may enforce the volume level of the speaker 250 to a determined limit. The processor 270 may communicate an alarm signal alert to listeners via the user interface 190. The alarm signal or alert may comprise an audio and/or visual alert. To maintain the speaker volume level within the determined volume level, the processor 270 may determine a set of filter coefficients to equalize the speaker 250, and select the gain adjustments levels of the audio signal for the volume control 224 and/or loudness control 226. The speaker equalizer 222, the volume control 224 and loudness control 226 may then be adjusted accordingly. Methods for determining these coefficients and gain levels may be implemented dependently. The loudness control 226 may provide the attenuated digital audio signal to digital to analog converter (DAC) 230 and the DAC 230 may provide an analog signal from the received attenuated digital audio signal from the loudness control 226. The analog audio signal may be coupled to the audio amplifier 240. The analog audio signal may be amplified at the audio amplifier 240 and outputted to the speaker 250. The audible sound signal may be broadcast from the speaker 250 accordingly.

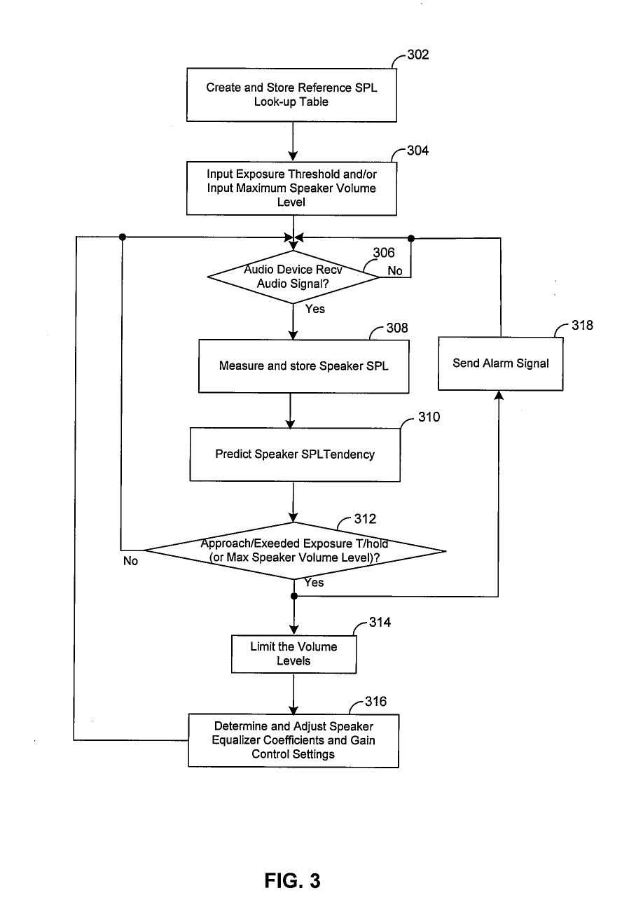

FIG. 3 is a flow chart that illustrates exemplary steps for determining audio signal processing parameters, in accordance with an embodiment of the invention. Referring to FIG. 3, the exemplary steps may begin in step 302, where the reference SPL information such as the SPL look-up table may be preloaded in the memory 280. The SPL look-up table uploading may be exercised only one time in the device life cycle such as in the manufacturing process or in a lab. In step 304, an exposure threshold on speaker SPL and/or maximum speaker volume level may be inputted via the user interface 190 to indicate user preferred settings. In step 306, check if the headset 102 may receive an audio signal. In instances where the headset 102 may receive an audio signal, then in step 308, the exposure meter 260 may provide instantaneous SPL measurements of the speaker 250, pass to the processor 270 and store in the memory 280.

In step 310, the processor 270 may predict a tendency of the speaker SPL based on the measured SPL values from the exposure meter 260 and respective reference SPL values stored in the memory 280. In step 312, the processor 270 may check whether the SPL of the speaker 250 may be approaching or have exceeded the exposure threshold and/or maximum speaker volume level based on the predicted SPL tendency in step 310. In instances where the SPL of the speaker 250 may approach or exceed the exposure threshold and/or maximum speaker volume level, then in step 314, the speaker exposure level and/or the volume level may be limited to a predetermined level which may be the respective upper limits or other user specific settings. In step 316, based on the speaker exposure level and/or the speaker volume level set in step 314, the processor 270 may determine corresponding speaker equalizer coefficients and gain control settings for the speaker equalizer 222, and/or the volume control 224, and/or the loudness control 226.

The speaker equalizer 222, and/or the volume control 224, and/or the loudness control 226 may be adjusted accordingly. In step 306, in instances where the headset 102 may not receive an audio signal, then stay in step 306. In step 312, In instances where the SPL of the speaker 250 may not approach and/or exceed the exposure threshold and/or maximum speaker volume level shortly, then go to step 306. In step 312, In instances where the SPL of the speaker 250 may approach and/or exceed the exposure threshold and/or maximum speaker volume level, then in step 318, the processor 270 may communicate an alarm or alert to listeners for the potential of high exposure levels. The next step may be step 306.

Aspects of a method and system for limiting an audio signal output in an audio device are provided. In accordance with various embodiments of the invention, an exposure meter 260 may used to provide measurements of speaker characteristics such as the sound pressure level (SPL) values of an audio signal. A measured SPL value of the audio signal may be mapped to a corresponding volume level of the audio signal. When the volume level of the audio signal may not be within a specified limit, the audio signal may be limited by enforcing the volume level of the audio signal to a predetermined value. The audio signal may be an input or an output signal of the speaker 250 of an audio device such as the headset 102. The processor 270 may be enabled to determine a trend of the measured SPL values over a certain time period based on the SPL measurements and reference SPL values stored in the memory 280. When the volume level of the audio signal may approach or exceed a specified limit, the audio signal may be limited and an alarm signal comprising an audio and/or visual alert may be sent out to listener via the user interface 290 by the processor 270. Accordingly, a set of audio volume level parameters, such as, for example, the coefficients of the speaker equalizer 222, the loudness level of the loudness control 226, and the volume level settings of the volume control 224, may be determined at the processor 270 based on the enforced volume level.

Another embodiment of the invention may provide a machine-readable storage, having stored thereon, a computer program having at least one code section executable by a machine, thereby causing the machine to perform the steps as described herein for limiting audio output in audio headsets.

Accordingly, the present invention may be realized in hardware, software, or a combination of hardware and software. The present invention may be realized in a centralized fashion in at least one computer system, or in a distributed fashion where different elements are spread across several interconnected computer systems. Any kind of computer system or other apparatus adapted for carrying out the methods described herein is suited. A typical combination of hardware and software may be a general-purpose computer system with a computer program that, when being loaded and executed, controls the computer system such that it carries out the methods described herein.

The present invention may also be embedded in a computer program product, which comprises all the features enabling the implementation of the methods described herein, and which when loaded in a computer system is able to carry out these methods. Computer program in the present context means any expression, in any language, code or notation, of a set of instructions intended to cause a system having an information processing capability to perform a particular function either directly or after either or both of the following: a) conversion to another language, code or notation; b) reproduction in a different material form.

While the present invention has been described with reference to certain embodiments, it will be understood by those skilled in the art that various changes may be made and equivalents may be substituted without departing from the scope of the present invention. In addition, many modifications may be made to adapt a particular situation or material to the teachings of the present invention without departing from its scope. Therefore, it is intended that the present invention not be limited to the particular embodiment disclosed, but that the present invention will include all embodiments falling within the scope of the appended claims.

What is claimed is:

1. A method for processing audio signals, the method comprising:
measuring a sound pressure level of an audio signal; and
limiting said audio signal when a volume level indicated by said measured sound pressure level is not within a specified limit.

2. The method according to claim 1, wherein said audio signal is generated from a speaker.

3. The method according to claim 1, wherein said audio signal is an input signal to a speaker.

4. The method according to claim 1, comprising predicting a trend of speaker characteristics based on said measured sound pressure level.

5. The method according to claim 4, comprising adjusting a gain of an equalizer that controls said volume level of said audio signal based on said predicted trend of speaker characteristics while limiting said audio signal.

6. The method according to claim 1, comprising adjusting one or more frequency components of said audio signal while limiting said audio signal.

7. The method according to claim 1, comprising determining whether an exposure level of said volume level of said audio signal is within said specified limit.

8. The method according to claim 1, comprising communicating an alarm signal or alert when said volume level of said audio signal is not within said specified limit.

9. The method according to claim 8, wherein said alarm signal or alert is an audio and/or visual alert.

10. A system for processing audio signals, the system comprising:
one or more circuits that measures a sound pressure level of an audio signal; and
said one or more circuits limits said audio signal when a volume level indicated by said measured sound pressure level is not within a specified limit.

11. The system according to claim 10, wherein said audio signal is generated from a speaker.

12. The system according to claim 10, wherein said audio signal is an input signal to a speaker.

13. The system according to claim 10, wherein said one or more circuits are enabled to predict a trend of speaker characteristics based on said measured sound pressure level.

14. The system according to claim 10, wherein said one or more circuits are enabled to adjust a gain of an equalizer that controls said volume level of said audio signal based on said predicted trend of speaker characteristics while limiting said audio signal.

15. The system according to claim 10, wherein said one or more circuits are enabled to adjust one or more frequency components of said audio signal while limiting said audio signal.

16. The system according to claim 10, wherein said one or more circuits are enabled to determine whether an exposure level of said volume level of said audio signal is within a specified limit

17. The system according to claim 16, wherein said one or more circuits are enabled to send out an alarm signal comprising an audio and/or visual alert when said volume level of said audio signal is not within said specified limit.

18. A machine-readable storage having stored thereon, a computer program having at least one code section for processing audio signals, the at least one code section being executable by a machine for causing the machine to perform steps comprising:
measuring a sound pressure level of an audio signal; and
limiting said audio signal when a volume level is not within a specified limit.

19. The machine-readable storage according to claim 18, wherein said audio signal is generated from a speaker.

20. The machine-readable storage according to claim 18, wherein said audio signal is an input signal to a speaker.

21. The machine-readable storage according to claim 18, wherein said at least one code section comprises code for predicting a trend of speaker characteristics based on said measured sound pressure level.

22. The machine-readable storage according to claim 21, wherein said at least one code section comprises code for adjusting a gain of an equalizer that controls said volume level of said audio signal based on said predicted trend of speaker characteristics while limiting said audio signal.

23. The machine-readable storage according to claim 21, wherein said at least one code section comprises code for adjusting one or more frequency components of said audio signal while limiting said audio signal.

24. The machine-readable storage according to claim 21, wherein said at least one code section comprises code for determining whether an exposure level of said volume level of said audio signal is within a specified limit.

25. The machine-readable storage according to claim 21, wherein said at least one code section comprises code for sending out an alarm signal when said volume level of said audio signal is not within said specified limit.
